(19) United States
(12) Patent Application Publication
(10) Pub. No.: US 2014/0293553 A1
(43) Pub. Date: Oct. 2, 2014

(54) MODULAR SOLAR BOX

(71) Applicants: Daniel Stanelli, Wattwil (CH); Markus Zahner, Jona (CH)

(72) Inventors: Daniel Stanelli, Wattwil (CH); Markus Zahner, Jona (CH)

(21) Appl. No.: 14/123,720

(22) PCT Filed: May 30, 2012
(86) PCT No.: PCT/EP2012/060179

§ 371 Date: May 13, 2014

(30) Foreign Application Priority Data
Jun. 3, 2011 (CH) 0094311

(51) Int. Cl. H01L 31/048; H05K 5/02

(52) U.S. Cl. CPC H01L 31/0485; H05K 5/0247
USPC 361/730

(57) ABSTRACT

The invention relates to a solar box (1) with a connection box (2) and at least one extension module (3, 20), which can be operatively connected to the connection box (2) via a first and a second connector part (9, 10) of a standardized interface (8). The connection box includes a connection shaft (5), into which contacts (7) lead from a shaft wall (11). The contacts (7) and the standardized interface (9) are arranged on the same shaft side.

### BACKGROUND OF THE INVENTION

1. Field of the Invention

The present invention is in the field of solar technology and relates to a solar box for connecting wiring to a solar panel.

2. Discussion of Related Art

Photovoltaic solar systems generally have a modular design and are composed of a plurality of solar cells, which are connected via external wiring. So as to achieve higher voltage, the individual solar cells are connected in series at least in groups by connecting the positive terminal of a first solar cell to the negative terminal of a further solar cell. One problem is that a solar cell becomes passive when it is partially covered, for example due to surrounding objects or clouds casting a shadow, and contributes little to the production of electricity, or not at all. As a result, the current of the neighboring solar cell flows through the covered solar cell in the case of a series connection, which may cause the cell to become damaged or at least reduces the service life thereof. For this reason, it is known for solar cells to be temporarily bypassed by way of an electronic circuit, which generally has diodes as protective elements, and for them to thereby be decoupled from power production during the interference. These electronic circuits are often accommodated in junction boxes, which are also used to connect the wiring.

WO2008/000101 from the same applicant was published in 2008 and shows a junction box comprising a housing bottom and a housing top, which can be operatively connected thereto and has a retaining means for receiving a printed circuit board. The housing bottom generally comprises a pedestal, which is used to mount the junction box to a flat and/or curved surface. One advantage is that the base plate can be secured first, especially in constraint spaces. The housing bottom, which is suited to receive the housing top, can then be operatively connected to the base plate.

WO2008/124951 from the same applicant was published in 2008 and shows a junction box comprising a housing and a connection duct, which is used to connect the junction box to electrical terminals of a solar panel. The housing has a protruding mounting pedestal, which is used to attach the junction box to a surface of the solar panel. The mounting pedestal is designed so that the rear wall of the housing has a distance from the solar panel when installed so that convectional cooling of the housing is achieved.

WO2006/050890 from Solarwatt AG was published in 2006 and relates to a connection unit for photovoltaic solar modules. The junction box has a duct with a rigidly attached frame, which is seated on the rear of the solar panel over a large surface area and can be pushed into the cooling fins as a module. One disadvantage of this device is that the device is very cost-intensive and nonetheless has a comparatively large height. Mounted on a solar panel, this reduces the ability to stack the solar panel, and additionally increases the risk of damage during transport and installation. In particular the cooling finds protrude significantly over the rear side and may easily damage the sensitive front side of a solar panel.

U.S. Pat. No. 5,951,785 from Sanyo Electric Ltd. was published in 1997 for the first time and described a system of an inverter for a solar cell module. The direct current of the solar cell module can be converted into an alternating current by way of the inverter. For improved cooling, the inverter is disposed at a distance from the rear wall of a solar cell module. The mounting and advantageous mutual positioning of the housings are not apparent from US '785.

The solar boxes for solar panels known from the prior art have the drawback that they have large builds and are not suited for flexible assembly. In particular a flexible expansion of the functions is not provided for in the junction boxes presently available. Another drawback is that maintenance on the solar boxes known from the prior art are very difficult to carry out. For example, one of the problems is that the failure of one solar box generally impacts several neighboring solar panels. Another problem is that the known solar boxes are protected only poorly against outside influences.

### SUMMARY OF THE INVENTION

It is an object of the invention to provide a solar box for a solar panel which does not have the inherent problems from the prior art.

This object is achieved by the solar box defined in the claims.

A solar box according to the invention comprises a multi-part housing, or several individual housings, which can be operatively connected, both mechanically and electrically, to each other by way of a defined interface. The multiple individual housings are advantageously separated according to the functions thereof and designed so that they allow a functional expansion and/or reconfiguration of the solar box at a later time. This then allows a solar panel to be flexibly adapted to new requirements, for example when new laws take effect.

In addition to electrical contacts, the standardized interface also has mechanical operative connecting means, which are designed to be durable even over extended periods of time (several years). The operative connecting means are advantageously disposed diametrically laterally and/or at the bottom and top of a plane or perpendicularly to the electrical contacts, resulting in a balanced distribution of forces. The operative connecting means are advantageously designed to be self-locking, so that two housing parts cannot be connected without the use of a tool.

In addition to a junction box, a solar box according to the invention generally comprises at least one further module, which is operatively connected to the junction box by way of the standardized interface. The at least one module is advantageously disposed so that the same has a certain gap with respect to the solar panel so as to achieve better cooling. If needed, it is also possible to interconnect a plurality of modules by way of the standardized interface. The standardized interface comprises the necessary number of mechanical and electrical contacts for this purpose.

In one embodiment, the solar box comprises a junction box having a connection duct for the electrical operative connection to connection strips of a solar panel. The connection duct is delimited by the housing of the junction box and can be closed with a cover. If needed, the connection duct can be designed so as to be potted. Electronics may be integrated in the junction box if needed. The junction box advantageously has a mounting surface (pedestal), by way of which the housing of the junction box can be attached to a surface of a solar panel by gluing. The mounting surface is advantageously designed to extend peripherally around the connection duct.

In a preferred embodiment, the junction box has a standardized interface, which has a right angle to the connection duct. The center line is advantageously located less than 3 cm away from the mounting surface of the junction box. Depending on the field of application, other heights may be selected.

One embodiment of the invention relates to a solar box having a junction box and at least one expansion module, which when assembled is operatively connected to the junction box by way of a first and a second connector part of a standardized interface. The junction box comprises a connection duct, into which contacts lead or protrude from at least one duct wall. The contacts and the standardized interface are disposed on the same duct side and are advantageously formed by the same parts, wherein the contacts may protrude directly into the first connector part of the standardized interface. If needed, the contact are disposed in such a way that they are also compatible with differently configured connection strips of different solar panels. This has the advantage that different junction boxes are not necessary.

The contacts may be designed in one piece, resulting in the least amount of loss. Good results are achieved by producing the contacts by way of stamping from sheet metal. The junction box generally has a pedestal, which is used to attach the junction box to a surface of a solar panel. The first connector part is disposed vertically offset relative to the pedestal. The pedestal is advantageously designed so that it surrounds the connection duct. Depending on the field of application, the connection duct may also be designed to be open on one side. The junction box advantageously comprises mechanical operative connecting means, by way of which an expansion module can be mechanically operatively connected to a housing of the junction box by way of second operative connecting means. The solar box may comprise electronic components. These may assume the following functions: theft protection, central deactivation/power enable (maintenance/repair), emergency off/fire protection (protection in the event a fire erupts/extinguishing), arcing detection (fire prevention), MPPT (maximum power point tracking, performance optimization), micro-inverter (MPPT+DC/AC conversion), and data acquisition (serial number, current, voltage, temperatures). The electronic components are integrated either into the junction box and/or at least into one of the expansion modules. In a preferred embodiment, the connecting cables are formed on an expansion module. In this case, electronic components may be integrated in the expansion module which allow the solar panel to be decoupled during operation. The junction box may further comprise mechanical operative connecting means that are suited for connecting a retaining rail. In this case, an expansion module comprises guide means, which can be operatively connected to the retaining rail. As an alternative, the expansion module may be rigidly operatively connected to the retaining rail. The expansion module is advantageously disposed at a distance from the surface of the solar panel so that an air gap results between the solar panel and the added module, bringing about optimal cooling.

The standardized interfaces are advantageously designed so that they can be electrically and mechanically operatively connected by pushing the housing parts together in one spatial direction. The standardized interfaces may also be designed so that they can be operatively connected by way of a rotational movement.

### BRIEF DESCRIPTION OF THE DRAWINGS

The invention will be described in greater detail based on the exemplary embodiments shown in the following drawings and the related descriptions. In the drawings:

FIG. 1 shows a perspective illustration of a first embodiment of a solar box obliquely from the front and above;

FIG. 2 shows a perspective illustration of the solar box of FIG. 1 obliquely from the back and above;

FIG. 3 shows a perspective illustration of the solar box of FIG. 1 obliquely from the front and the back;

FIG. 4 shows a side view of the solar box of FIG. 1;

FIG. 5 shows a perspective illustration of a second embodiment of a solar box obliquely from the front and above;

FIG. 6 shows a perspective illustration of the solar box of FIG. 5 obliquely from the back and above;

FIG. 7 shows a perspective illustration of the solar box of FIG. 5 obliquely from the front and behind;

FIG. 8 shows a side view of the solar box of FIG. 5;

FIG. 9 shows an expanded configuration of the solar box of FIG. 5;

FIG. 10 shows a perspective illustration of the solar box of FIG. 9 obliquely from beneath and the front;

FIG. 11 shows a perspective illustration of a third embodiment of a solar box obliquely from the back and above;

FIG. 12 shows the solar box of FIG. 11 obliquely from the front and beneath;

FIG. 13 shows a variant of the solar box of FIG. 11 obliquely from the back and above;

FIG. 14 shows the solar box of FIG. 11 obliquely from the front and above in the assembled state;

FIG. 15 shows the solar box of FIG. 11 from the front and beneath;

FIG. 16 shows a perspective illustration of a fourth embodiment of a solar box obliquely from the front and above; and

FIG. 17 shows detail D of FIG. 16.

Identical reference numerals are used in the figures below for corresponding parts/areas.

### DETAILED DESCRIPTION OF THE INVENTION

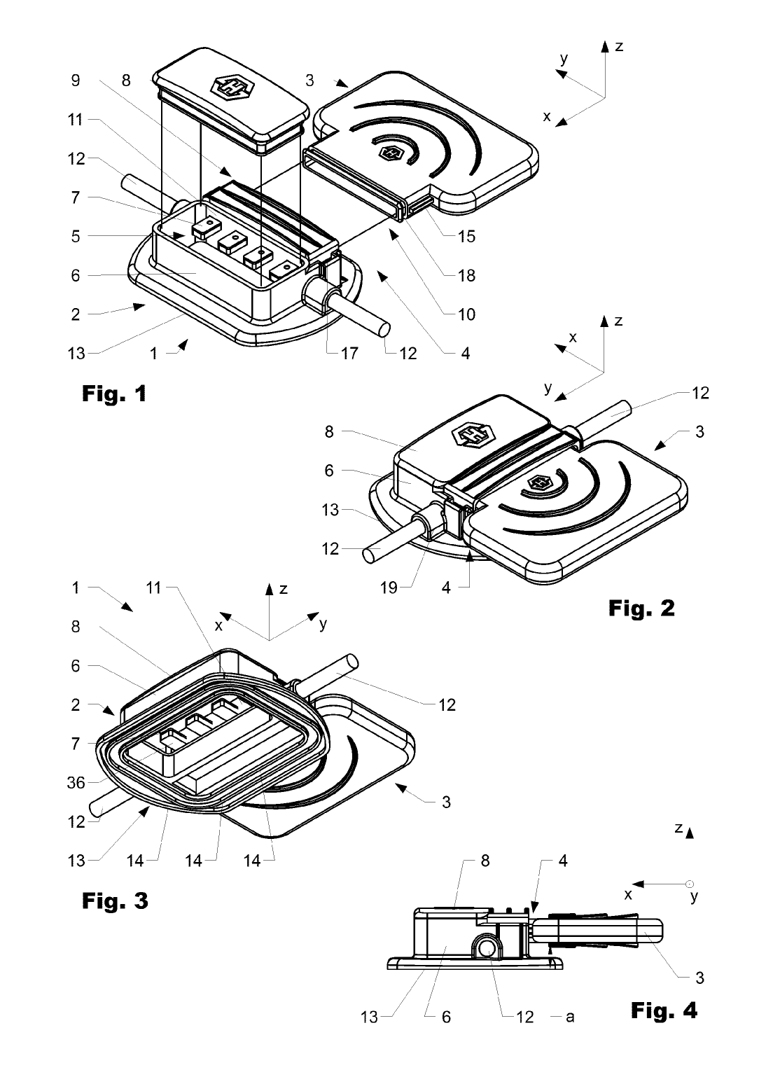

FIG. 1 shows a perspective illustration of a first embodiment of a solar box 1 according to the invention obliquely from the front and above. FIG. 2 shows a perspective illustration the solar box 1 according to the invention obliquely from the back and above. FIG. 3 shows a perspective illustration of the solar box 1 obliquely from the front and behind, and FIG. 4 shows a side view of the solar box 1.

The illustrated solar box 1 is composed of a junction box 2 and an expansion module 3, which can be operatively connected to the junction box 2 from the side (x-direction) by way of a standardized interface 4. The standardized interface 4 is used to transmit power and, if necessary, data. At the same time, the interface also brings about mechanical mounting of the expansion module 3 with respect to the junction box 2. While the junction box 2 is primarily used to attach the solar box 1 to a solar panel (not shown in detail), the expansion module 3 is used to receive electronic components such as diodes and the like, which are relevant for controlling the function of a connected solar panel or for the processing of data.

FIG. 1 shows the solar box 1 in the disassembled state. The individual housings are shown separately from each other. The junction box 2 has a connection duct 5, which is formed by a housing 6. Contacts 7 protrude from the side into the connection duct 5 and are used for connection to corresponding contact strips of the solar panel (both of them are not shown in detail). The contacts 7 are formed on a duct side that faces the expansion module 3. The connection duct 5 can be closed by a cover 8. The standardized interface 4 has a first connector part 9 located on the junction box side (with respect to the housing) and a second connector part 10 located on the expansion module side. In the embodiment shown, the contacts 7 protrude directly into the first connector part 9 and are advantageously formed in one piece, for example from sheet metal. On the duct side, they protrude from a duct wall 11 and are advantageously disposed in such a way that they are compatible with the terminals of one or more solar panels. The housing 6 is advantageously produced from plastic material by way of injection molding. The contacts 7 can be inserted as separate parts into the mold and encapsulated. As an alternative, they may be pressed into a previously produced housing. In a further embodiment, the housing 6 has a multi-part design, so that the contacts 7 are inserted into a first housing part and this part is then closed with a second housing part.

In the embodiment shown in FIGS. 1 to 4, the junction box comprises connection cables 12, which are used to connect the solar box 1. The connection cables 12 are formed laterally on the junction box 2. The connection cables 12 are in operative connection with the contacts 7 and the expansion module 3.

If needed, relevant electronic components may be integrated into the housing 6 of the junction box 2, for example for fundamentally controlling the function. For example, there is the option to integrate diodes (not shown in detail) used to bypass a solar panel in the event of shade and/or other control electronics into the junction box 2. These elements are advantageously disposed between the connection duct 5 and the first connector part 9.

As can be seen in FIG. 3, the housing 6 comprises a pedestal 13, which peripherally surrounds the connection duct 6. The pedestal 13 is used to glue the junction box 2 to a surface of a solar panel. The pedestal comprises a plurality of downwardly protruding ribs 14, which bring about better bonding of the adhesive.

In the embodiment shown, the contacts 7 are disposed horizontally (x-y plane) on the carrier elements 36 protruding from the duct wall 11, the elements supporting the contacts 7 in particular when the contact strips of a solar panel are connected. As the solar panel is contacted, it is insulated against high temperatures at the same time. If needed, the contacts can also be disposed so as to stand up vertically or extend in an oblique plane, so that they may be contacted laterally or at a particular angle.

As can be seen in the side view (y-direction) shown in FIG. 4, the standardized interface 4 is disposed in the region of the upper end of the duct 5. When operatively connected, the expansion module 3 has a distance a, resulting in an air gap between the solar panel and the expansion module. The distance a causes improved cooling. If necessary, the expansion module 3 may comprise cooling fins. If needed, the expansion module 3 may in addition be directly or indirectly supported or fixed on the solar panel. The solar box 1 shown has a simple design that is cost-effective to produce and exhibits a comparatively good cooling behavior. The forces for mounting the expansion module 3 are transmitted via the standardized interface 4. The standardized interface 4 comprises mechanical operative connecting means 15, 16 for this purpose, which are used to fix the expansion module 3 with respect to the junction box 2. As can be seen in FIG. 1, in the embodiment shown the operative connecting means 15, 16 are composed of combs 15, which are disposed on both sides of the second connector part 10 and engage in corresponding grooves 16 of the second connector part 9, or may be snap-fit into these, and bring about a stable, permanent mechanical connection. In the embodiment shown, the mechanical connection can be undone by introducing a tool, for example a screwdriver, into unlocking openings 17 formed laterally on the housing 6. This causes snap-fit elements (not visible) disposed on the inside to be brought into an unlocking position, whereby the expansion module is released. A lateral arrangement of the operative connecting means achieves a good distribution of forces. In addition, the second connector part has a peripheral groove 18 for receiving a gasket (not shown).

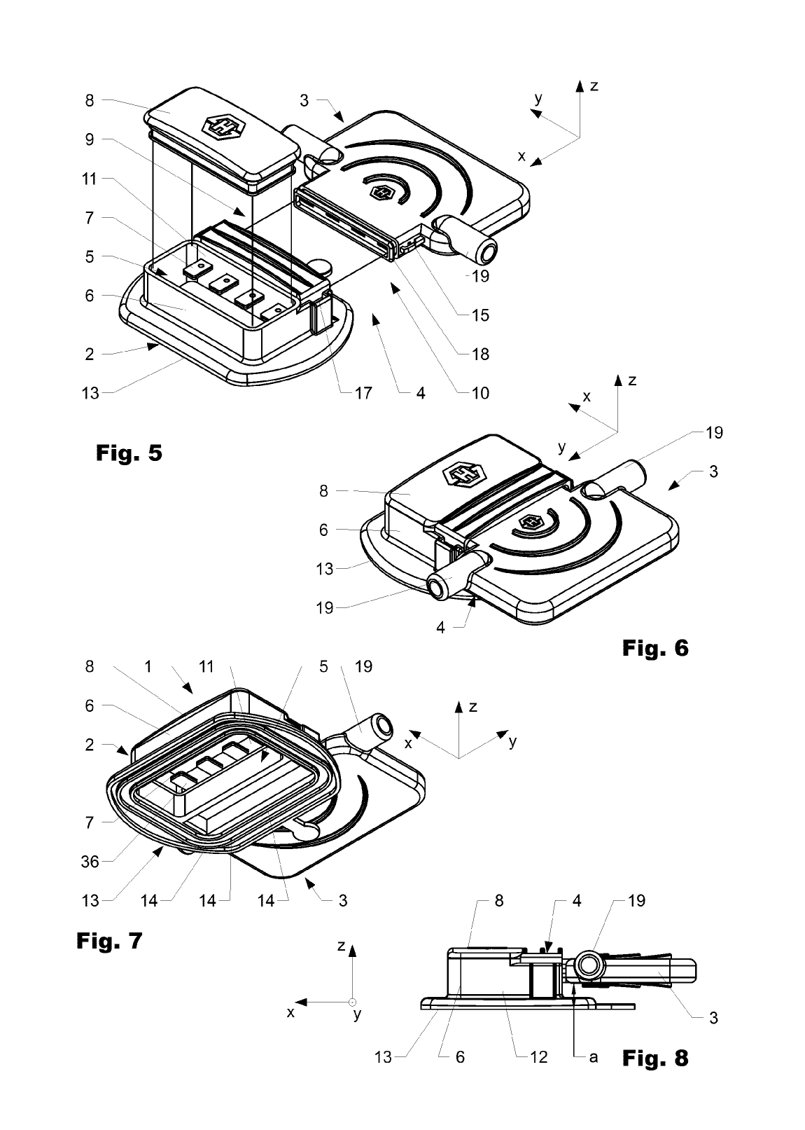

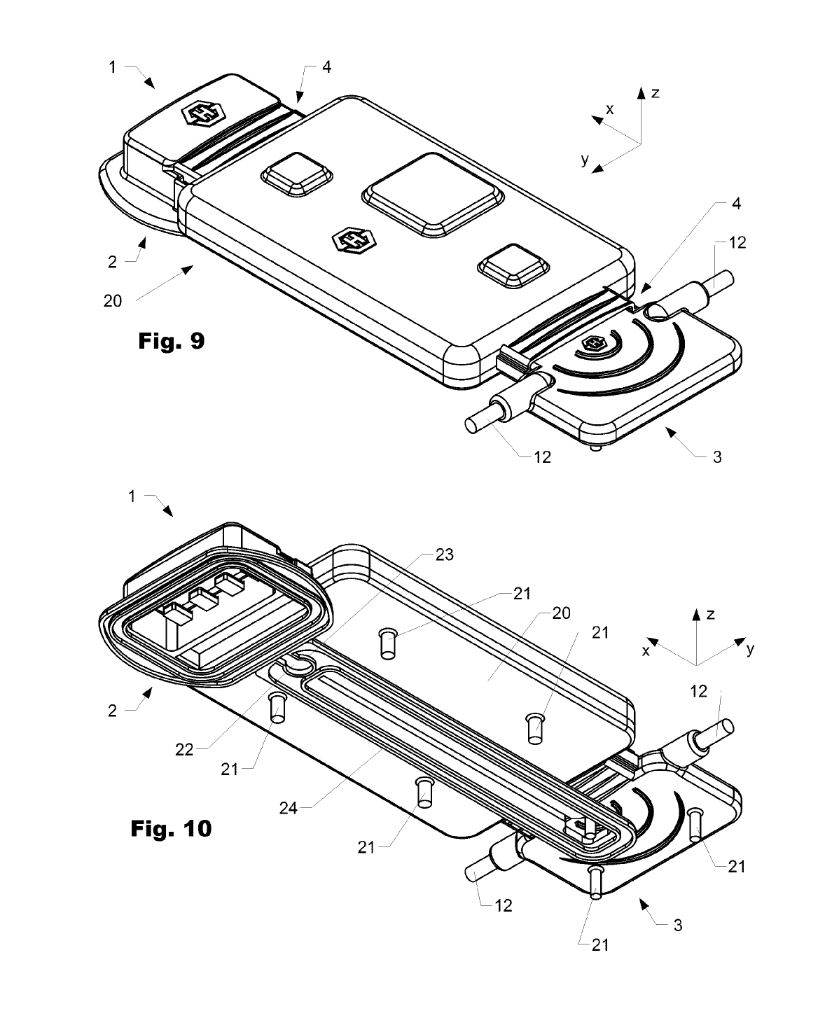

FIGS. 5 to 8 show a further embodiment of a solar box 1 according to the invention. The design and operating principle essentially correspond to the embodiment shown in FIGS. 1 to 4, so that reference is made to those figures for the general description and only the differences will be addressed here. In the second embodiment, the connection cables (shown schematically here based on cable openings 19) are not provided on the junction box 2, but on the expansion module 3. The expansion module 3 and the cables may thus be pre-assembled, if needed, and during installation only have to be operatively connected to the junction box 2 that is attached to the solar panel. Another advantage is that the solar panel may be separated by unplugging the expansion module 3 without interrupting further solar panels connected in series. This is advantageous in particular in the event of a defect of a solar panel because this assures easy replacement. The expansion module, or the junction box 2, comprises means that prevent arcing. Another advantage is that the solar box 1—as is shown in FIGS. 9 and 10—can be flexibly expanded.

FIGS. 9 and 10 show an expanded configuration of the solar box 1 according to FIGS. 5 and 8. Reference is made to the description of the preceding figures with respect to the general operating principle. FIG. 9 shows the solar box obliquely from above and the back, and FIG. 10 shows it obliquely from beneath and the front. A second expansion module 20 is inserted between the junction box 2 and the expansion module 3, this second module comprising an electronic circuit for the open-loop and/or closed-loop control of the function of a connected solar panel. The second expansion module 20 is used to flexibly expand the function of the solar box 1. The second expansion module 20 is operatively connected to the junction box 2 and the first expansion module 3 by way of standardized interfaces 4 and cooperates—if any are present—with electronic components integrated in the junction box and first expansion module. Otherwise, the second expansion module is used to transmit power from the junction box 2 to the first expansion module 3, to which the cables 12 are connected for operative connection to the outside.

As can be seen in FIG. 10, in the embodiment shown both the first and the second expansion module 3, 20 have one or more feet 21, which are used for direct or indirect support on the surface of a solar panel. If needed, the feet 21 may comprise one or more pedestals, which are suited for attachment to a surface of a solar panel. The feet 21 cause the rear walls of the first and second expansion modules 3, 20 to be disposed at a particular distance from the solar panel, which contributes to improved cooling. If no or only little cooling is required in an expansion module, the module may also be designed so as to rest directly on the surface of a solar panel. Moreover, the junction box 2 comprises a first coupling part 22, which can be operatively connected to a second coupling part 23 of a retaining rail 24. The retaining rail 24 is designed as a separate part and can also be flexibly retrofitted if needed. The retaining rail 24 is designed so that it can be attached to the surface of a solar panel, for example by gluing. If needed, the retaining rail 24 may be rigidly operatively connected to the second expansion module 20. The retaining rail 24 is used, among other things, to precisely position the expansion modules 3, 20 with respect to the junction box 2.

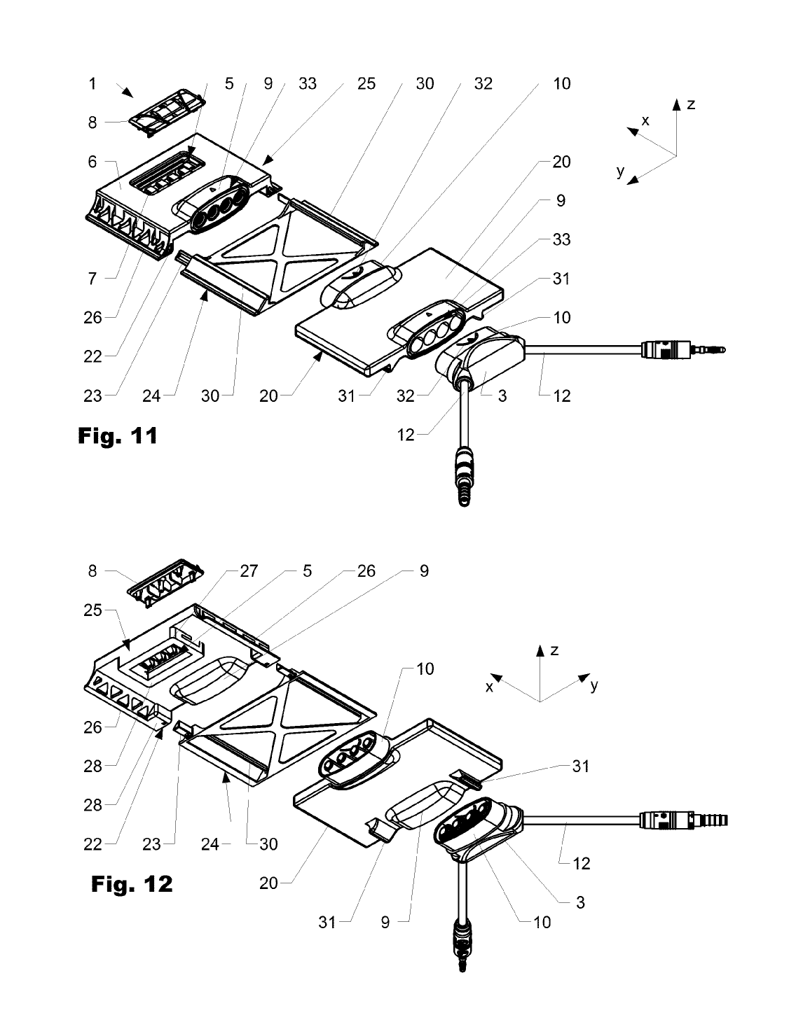

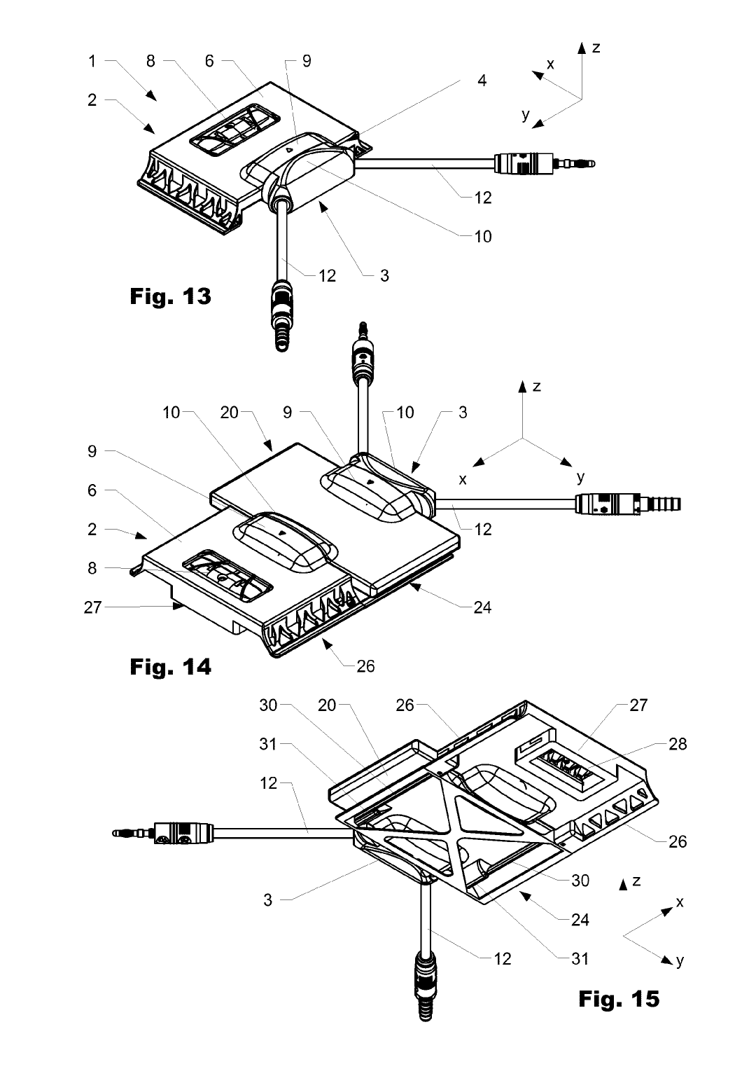

FIGS. 11 to 15 show a third embodiment of a solar box 1. This box is also composed of a junction box 2 and a first and a second expansion module 3, 20. FIGS. 11 and 12 show the solar box in the removed state, so that the design is better visible. FIGS. 13 to 15 show the individual modules when they are operatively connected.

The junction box 2 again has a connection duct 5, which is formed by a housing 6 of the junction box 2. Contacts 7 are disposed in the connection duct 5, which are operatively connected to a first connector part 9. The connection duct 5 can be closed by a cover 8.

The contacts 7 are essentially disposed at the level of the first connector part 9. This has the advantage that the interior of the junction box 2 can have a simple design. In the embodiment shown, the junction box 2 has a multi-part pedestal 25, which here comprises two laterally disposed supports 26 extending along a longitudinal edge. The pedestal 25 further comprises a second region 27 surrounding the connection duct 5. The pedestal 25 causes the rear wall of the junction box 2 to be lifted off the surface of a solar panel, which contributes to improved cooling. Both the first and the second part 26, 27 of the pedestal 25 comprises surfaces 28 that are used to receive an adhesive substance or double-sided adhesive tape. The pedestal 25 causes a rear wall 29 of the junction box 2 to be lifted off/spaced from a solar panel and thereby improves cooling. The support 26 comprises concave first coupling parts 22 in the form of openings, which are used for the engagement of what here are pin-shaped second coupling parts 23 of a retaining rail 24. The upper face of the retaining rail 24 comprises first guide means 30, which are suited for receiving second guide means 31 formed on the second expansion module 20. The retaining rail 24 may also be an integral part of a second expansion module 3, 20 and may be operatively connected together therewith to the junction box 2. One advantage of the embodiment shown is that, during installation, the retaining rail 24 can be plugged into a junction box 2 and then be attached to a surface of a solar panel. An expansion module 20 can then be pushed into the rail in the direction of the junction box 2 and operatively connected thereto by way of the connector parts 9, 10 of the standardized interface 4. Mechanical locking takes place by way of the standardized interfaces or further operative connecting means.

FIG. 13 illustrates the solar box 1 in a simple configuration having only one first expansion module 3. The first expansion module 3 comprises the cables 12 by way of which the solar box is connected from the outside. The connector parts 9, 10 of the standardized interface 4 comprise mechanical operative connecting means 32, 33 (refer to FIG. 11), which are disposed on the bottom and top with respect to the connector parts 9, 10, respectively.

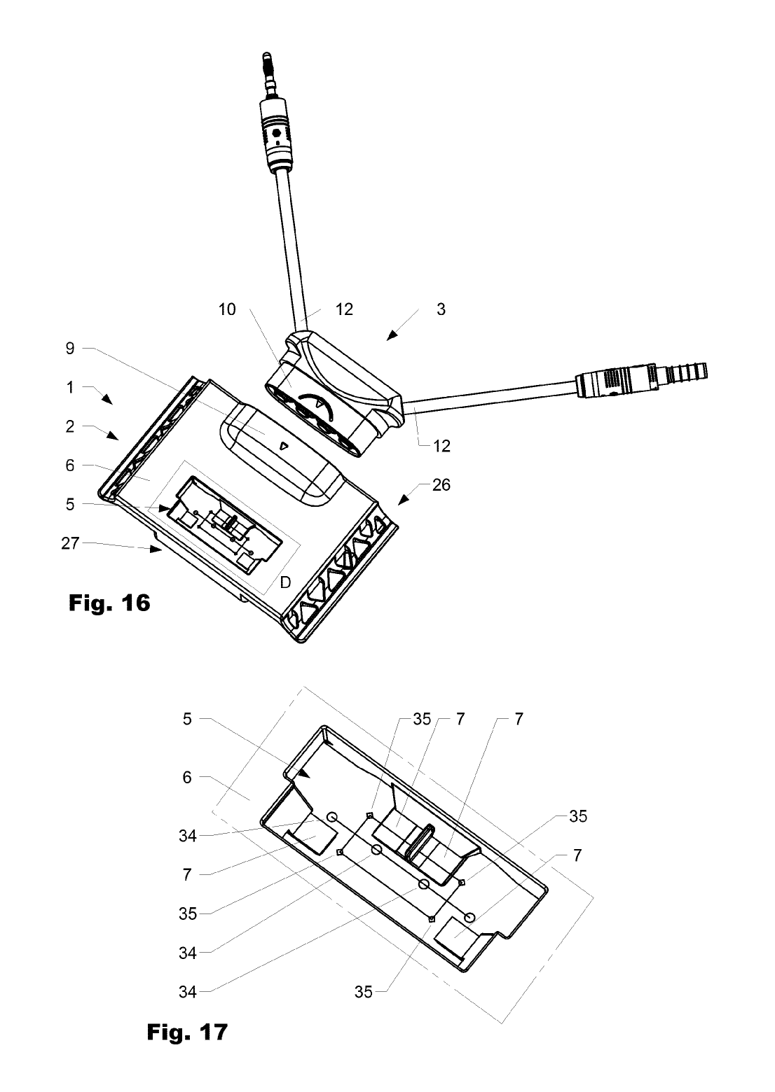

FIG. 16 shows a perspective illustration of a fourth embodiment of a solar box 1 obliquely from the front and above. FIG. 17 shows an enlarged illustration of detail D from FIG. 16. The solar box 1 essentially corresponds to the embodiment shown in FIG. 13, so that reference is made to the related figures with respect to the general description. In the configuration shown, the solar box 1 comprises a junction box 2 and a first expansion module 3. Contrary to the preceding embodiments, the variant shown in FIG. 16 comprises a connection duct 5 having a special arrangement of the contacts 7, which are formed on different duct walls 11 so as to protrude into the duct interior.

The connection duct 5 is formed by the housing 6 of the junction box 2. The duct extends in the vertical direction (z-direction), is closed here on four sides and disposed close to the edge. The contacts 7 here are made of sheet metal and protrude horizontally into the duct 5 close to the bottom (near the duct end on the rear wall side). The contacts are disposed in such a way that they are compatible with differently arranged connection strips of different solar panels. Two different arrangements of connection strips of solar panels are schematically indicated by circles 34 (four contact strips on one line next to each other, 4×1 arrangement), and rhombi 35 (rectangular arrangement of the contact strips, 2×2 arrangement). The contacts 7 are disposed in such a way that they are compatible with the differently arranged connection strips 34, 35. In the embodiment shown, the contacts 7 are disposed on three duct walls. Other arrangements are possible, in which the shown positions 34, 35 may be occupied simultaneously. For example, the contacts 7 may be designed to have differing lengths and can project from only one duct wall. As an alternative, the contacts may be formed on two opposing duct walls. Moreover, the contacts may be designed to stand up vertically and, if necessary, may have one or more bends or curves. For example, the contacts may have an L-shaped cross-section and be disposed in a vertically standing manner. This allows the contact strips to be contacted without having to bend these over. The special arrangement of the contacts 7 may also be integrated into the embodiments shown and described in the preceding figures.

One advantage of the embodiments shown is that they enable a very small height ranging between 3 and 5 cm. Because of the very flat but nonetheless robust design, the solar boxes shown do not impair the ability to stack common solar panels since they can be installed inside the frames thereof.

1. A solar box (1), comprising:
a junction box (2); and
at least one expansion module (3, 20), operatively connected to the junction box (2) by way of a first and a second connector part (9, 10) of a standardized interface (4), wherein the junction box (2) comprises a connection duct (5) into which contacts (7) lead from at least one duct side, and wherein when installed, the at least one expansion module (3, 20) includes a distance (a) from a solar panel, resulting in a gap.

2. The solar box (1) according to claim 1, wherein the solar box (1) comprises a first expansion module (3) having connection cables (12).

3. The solar box (1) according to claim 2, wherein the first expansion module (3) comprises electronic components, which allow a solar panel to be decoupled during operation.

4. A solar box (1) according to claim 1, wherein the contacts (7) are disposed so that they are also compatible with differently configured connection strips (34, 35) of different solar panels.

5. A solar box (1) according to claim 1, wherein the contacts (7) are disposed horizontally and/or vertically.

6. A solar box (1) according to claim 1, wherein the contacts (7) are curved and/or bent.

7. The solar box according to claim 6, wherein the contacts (7) include an L-shaped cross-section.

8. A solar box (1) according to claim 1, wherein the junction box (2) comprises mechanical operative connecting means (15, 32), including at least one expansion module (3, 20) mechanically operatively connected by way of second operative connecting means (16, 33).

9. A solar box (1) according to claim 1, wherein the junction box (2) comprises at least one pedestal (25, 26, 27) to attach the junction box (2) to a surface of a solar panel.

10. A solar box (1) according to claim 1, wherein the pedestal (27) surrounds the connection duct (5).

11. A solar box (1) according to claim 1, wherein the junction box (2) comprises electronic components.

12. A solar box (1) according to claim 1, wherein the junction box (2) comprises mechanical operative connecting means (22, 23) for connecting a retaining rail (24).

13. A solar box (1) according to claim 12, wherein the expansion module (3) comprises guide means (31) operatively connected to the retaining rail (24).

14. A junction box (2) for use in a solar box (1) according to claim 1.

15. An expansion module (3) for use in a solar box (1) according to claim 1.
